(19) United States
(12) Patent Application Publication
(10) Pub. No.: US 2020/0186062 A1
(43) Pub. Date: Jun. 11, 2020

(54) RIPPLE COUNTING FILTERING AND PEAK DETECTION METHOD AND SYSTEM

(71) Applicant: MAGNA CLOSURES INC., Newmarket (CA)

(72) Inventors: Luca FANCELLU, Sassari (IT); Antonio FRELLO, Livorno (LI) (IT); Jacopo FANUCCHI, Collesalvetti (LI) (IT)

(21) Appl. No.: 16/704,144

(22) Filed: Dec. 5, 2019

Related U.S. Application Data
(60) Provisional application No. 62/776,049, filed on Dec. 6, 2018.

(51) Int. Cl. H02P 7/00; H02P 6/18; G01P 3/48; H02P 7/28; H02P 7/03; H03K 5/1532

(52) U.S. Cl. CPC H02P 7/0094; H02P 6/18; H03K 5/1532; H02P 7/2805; H02P 7/03; G01P 3/48

(57) ABSTRACT

A control system for controlling a mechanically commutated direct current electric motor and corresponding method of operation are provided. The control system includes a motor current sensing circuit for sensing a motor current comprising a plurality of ripples due to commutation of the motor and outputting a motor current signal. The control system also includes a controller including a finite state machine unit and is configured to detect the plurality of ripples in the motor current and to determine whether each of the plurality of ripples is a valid ripple using the finite state machine unit. The controller is also configured to count the plurality of ripples determined to be valid using the finite state machine unit and to determine at least one of a motor rotational position and a motor speed of the motor based on a quantity of the plurality of ripples determined to be valid.

### CROSS REFERENCE TO RELATED APPLICATION

This application claims the benefit of U.S. Provisional Application Ser. No. 62/776,049 filed Dec. 6, 2018. The entire disclosure of the above application is incorporated herein by reference.

### FIELD

The present disclosure relates generally to a method and system for monitoring and controlling an electric motor, more particularly to a method for determining at least one of a motor rotational position and a motor speed of a mechanically commutated direct current electric motor from a plurality of ripple peaks of a motor current due to commutation of the mechanically commutated direct current electric motor using a control system.

### BACKGROUND

This section provides background information related to the present disclosure which is not necessarily prior art.

Window regulators and other power operated actuators are commonly found on motor vehicles. Such power operated actuators may utilize mechanically commutated direct current (DC) motors. In many of these applications, it is desirable to monitor a rotational position and/or speed of a shaft of the motor to more accurately control movement of a mechanism of the power operated actuator (e.g., position of a window moveable by a window regulator). While position sensors, such as Hall effect sensors and rotary encoders may be used in conjunction with the motors, these additional sensors can also add cost, weight, and/or complexity. Accordingly, there remains a need for improved control systems for DC motors (e.g., used in power operated actuators) and methods of operation thereof that overcome these shortcomings.

### SUMMARY

This section provides a general summary of the present disclosure and is not a comprehensive disclosure of its full scope or all of its features and advantages.

It is an object of the present disclosure to provide a motor control system and a method of operating the control system that address and overcome the above-noted shortcomings.

Accordingly, one an aspect of the present disclosure to provide a control system for controlling a mechanically commutated direct current electric motor of a power operated actuator of a vehicle. The control system includes a motor current sensing circuit for sensing a motor current comprising a plurality of ripples due to commutation of the mechanically commutated direct current electric motor and outputting a motor current signal. The control system also includes a controller in communication with the motor current sensing circuit and including a finite state machine unit and the controller is configured to detect the plurality of ripples in the motor current and to determine whether each of the plurality of ripples is a valid ripple using the finite state machine unit. The controller is configured to count the plurality of ripples determined to be valid using the finite state machine unit and to determine at least one of a motor rotational position and a motor speed of the electric motor based on a quantity of the plurality of ripples determined to be valid.

According to another aspect of the disclosure, a method for determining at least one of a motor rotational position and a motor speed of a mechanically commutated direct current electric motor from a plurality of ripple peaks of a motor current due to commutation of the mechanically commutated direct current electric motor using a control system including a controller is provided. The method includes the step of preconditioning a motor current signal to isolate the plurality of ripple peaks during an established period of time. The method continues by detecting the plurality of ripple peaks in the motor current signal using a peak detection unit of the controller. The next step of the method is calculating a ripple period based on an estimated speed of the mechanically commutated direct current electric motor. The method proceeds with the step of determining which of the plurality of ripple peaks are above a detection threshold based on the state of the mechanically commutated direct current electric motor. Next, registering a first peak of the plurality of ripple peaks during the ripple period in response to one of the plurality of ripple peaks being above the detection threshold. The method then includes the step of ignoring subsequent ones of the plurality of ripple peaks for a predetermined period of time after registering the first peak. The method also includes registering one of a plurality successive peaks of the plurality of ripple peaks during another predetermined period of time in response to another of the plurality of ripple peaks being above the detection threshold after the expiration of the predetermined period of time. The method continues with the steps of counting a ripple count of the first peak and the plurality successive peaks being registered and determining at least one of the motor rotational position and the motor speed of the mechanically commutated direct current electric motor based on the ripple count.

According to yet another aspect of the disclosure, a control system for controlling a mechanically commutated direct current electric motor of a power operated actuator of a vehicle is also provided. The control system includes a motor current sensing circuit for sensing a motor current comprising a plurality of ripples due to commutation of the mechanically commutated direct current electric motor and outputting a motor current signal. The control system also includes a controller in communication with the motor current sensing circuit and including a peak detection unit. The controller is configured to detect the plurality of ripples in the motor current using the peak detection unit to register a first peak of the plurality of ripples during a ripple period in response to one of the plurality of ripples having a peak above a detection threshold. The controller is additionally configured to ignore subsequent ones of the plurality of ripples for a predetermined period of time after registering the first peak. In addition, the controller is configured to register one of a plurality successive peaks of the plurality of ripple during another predetermined period of time in response to another of the plurality of ripple peaks being above the detection threshold after the expiration of the predetermined period of time. The controller is also configured to calculate a ripple count based on the first peak and the plurality successive peaks being registered.

According to another aspect, there is provided a method for determining at least one of a motor rotational position and a motor speed of a mechanically commutated direct current electric motor from a plurality of ripple peaks of a motor current signal due to commutation of the mechanically commutated direct current electric motor, the method comprising the steps of detecting the plurality of ripple peaks in the motor current signal, determining whether each of the plurality of ripple peaks is a valid, counting the plurality of ripple peaks determined to be valid, and determining at least one of a motor rotational position and a motor speed of the electric motor based on a quantity of the plurality of ripple peaks determined to be valid.

According to another aspect, there is provided a system for determining at least one of a rotational position and a speed of a mechanically commutated direct current electric motor of a power actuator unit of a vehicle, comprising a motor current sensing circuit for sensing a motor current comprising a plurality of ripples due to commutation of the mechanically commutated direct current electric motor and outputting a motor current signal, and a controller in communication with the motor current sensing circuit, the controller configured to receive the motor current signal comprising a plurality of ripple peaks, determine whether the plurality of ripple peaks are valid, count the plurality of ripple peaks determined to be valid, and determine at least one of the rotational position and the speed of the electric motor based on a quantity of the plurality of ripple peaks determined to be valid.

According to another aspect, there is provided a control system for controlling at least one of a rotational position and a speed of a mechanically commutated direct current electric motor of a power actuator unit of a vehicle, comprising a motor control unit for a motor current sensing circuit for sensing a motor current comprising a plurality of ripples due to commutation of the mechanically commutated direct current electric motor and outputting a motor current signal, and a controller in communication with the motor current sensing circuit, the controller configured to receive the motor current signal comprising a plurality of ripple peaks, determine whether the plurality of ripple peaks are valid, count the plurality of ripple peaks determined to be valid, and determine at least one of the rotational position and the speed of the electric motor based on a quantity of the plurality of ripple peaks determined to be valid; and control the at least one of a rotational position and a speed of the motor using the determined determine at least one of the rotational position and the speed of the electric motor.

According to another aspect, there is provided a method for controlling a mechanically commutated direct current electric motor from a plurality of ripple peaks of a motor current signal due to commutation of the mechanically commutated direct current electric motor, the method comprising the steps of detecting the plurality of ripple peaks in the motor current signal, determining whether each of the plurality of ripple peaks is a valid, counting the plurality of ripple peaks determined to be valid, and determining at least one of a motor rotational position and a motor speed of the electric motor based on a quantity of the plurality of ripple peaks determined to be valid; and controlling the motor using the determined at least one of a motor rotational position and a motor speed of the electric motor based on a quantity of the plurality of ripple peaks determined to be valid.

According to another aspect, there is provided a ripple detection controller including a signal acquisition unit coupled to a motor voltage and current sensing circuit, a model estimate unit coupled to a signal acquisition unit, a signal filtering unit coupled to a signal acquisition unit and to the model estimate unit and a peak analysis unit coupled to the signal filtering unit, to model estimate unit and the signal acquisition unit 143, such that peak analysis unit is configured to output at least one of a motor speed, and a motor position, based on a plurality of validated ripple peaks.

According to another aspect, there is provided a detection system including a voltage and current variable sampling unit for sampling a motor current having a plurality of ripple peaks as a function of a motor speed, a speed estimator unit for generating an estimated motor speed based on a model of the motor, a sampling frequency computation unit for determining a sampling rate of the motor current signal as a function of the estimated motor speed, a frequency domain filter for isolating the ripple peaks in the motor current signal, a peak validator unit for validating the ripple peaks in the motor current signal before counting the ripple peaks in the motor current and/or for invalidating a validated ripple peak before counting the ripple peaks in the motor current signal, a peak detector unit for time filtering the filtered motor current signal for detecting the ripple peak, and a counter unit for counting the validated ripple peaks outputted from the peak detector unit.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a perspective view of a motor vehicle including moveable windows and closure panels, in accordance with an illustrative embodiment;

FIG. 2 is a side view of a closure panel having a moveable window and power actuator unit in accordance with an illustrative embodiment;

FIG. 3 is a side cross-sectional view of the power actuator unit of FIG. 2, in accordance with an illustrative embodiment;

FIG. 4 is a diagram of a brushed permanent magnet motor, in accordance with an illustrative embodiment;

FIGS. 5A and 5B show opposite sides of a printed circuit board having a controller of a control system for controlling an electric motor of the power actuator unit, in accordance with an illustrative embodiment;

FIG. 6A illustrates an example of a motor control system having a detection system, in accordance with an illustrative embodiment;

FIG. 6B illustrates a motor voltage and current sensing circuit of the control system, in accordance with an illustrative embodiment;

FIG. 7 illustrates a plurality of units of the controller in communication with the motor voltage and current sensing circuit, in accordance with an illustrative embodiment;

FIG. 8 illustrates a direct current removal digital filter unit of the controller, in accordance with an illustrative embodiment;

FIG. 9 shows an example plot of a frequency response of a digital bandpass filter unit of the controller, in accordance with an illustrative embodiment;

FIG. 10 illustrates an analysis of each of a plurality of possible peaks of a plurality of peak detector samples of a bandpass filtered current signal within a time window of a predetermined peak detection time using a peak detection unit of the controller, in accordance with an illustrative embodiment;

FIG. 11 illustrates a computation of a nearest point mean of a predetermined quantity of the plurality of peak detector samples before and after each of the plurality of possible peaks using the peak detection unit of the controller, in accordance with an illustrative embodiment;

FIG. 12 illustrates a comparison a magnitude of each of the plurality of possible peaks to the nearest point mean using the peak detection unit of the controller, in accordance with an illustrative embodiment;

FIG. 13 shows an example plot of a motor current during operation of the electric motor, in accordance with an illustrative embodiment;

FIG. 14 illustrates a stall condition in the detected motor current, in accordance with an illustrative embodiment;

FIGS. 15 and 16 show states of a finite state machine unit of the controller, in accordance with an illustrative embodiment;

FIG. 17 illustrates a logic diagram showing operation of the finite state machine unit with a stall condition and an under-speed condition, in accordance with an illustrative embodiment;

FIGS. 18 and 19 illustrate a time filter applied by the controller to ignore a predetermined quantity of ripple period samples, in accordance with an illustrative embodiment;

FIGS. 20-22 illustrate steps of a method for determining at least one of a motor rotational position and a motor speed of the electric motor from a plurality of ripple peaks of a motor current due to commutation using the control system, in accordance with an illustrative embodiment;

FIG. 23 is a flowchart illustrating the validation of a motor current signal using a finite state machine, in accordance with an illustrative embodiment;

FIG. 24 is a flowchart illustrating the validation of a motor current signal, in accordance with an illustrative embodiment; and

FIG. 25 is a block diagram of a detection system, according to an illustrative example.

### DETAILED DESCRIPTION

In the following description, details are set forth to provide an understanding of the present disclosure. In some instances, certain circuits, structures and techniques have not been described or shown in detail in order not to obscure the disclosure.

The expression “closure panel” will be used, in the following description and the accompanying claims, to generally indicate any element movable between an open position and a closed position, respectively opening and closing an access to an inner compartment of a motor vehicle, therefore including, boot, doors, liftgates, sliding doors, rear hatches, bonnet lid or other closed compartments, windows, sunroofs, in addition to the side doors of a motor vehicle.

In general, the present disclosure relates to a control system of the type well-suited for use in many electric motor applications. The control system and associated methods of operation of this disclosure will be described in conjunction with one or more example embodiments. However, the specific example embodiments disclosed are merely provided to describe the inventive concepts, features, advantages and objectives with sufficient clarity to permit those skilled in this art to understand and practice the disclosure. Specifically, the example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

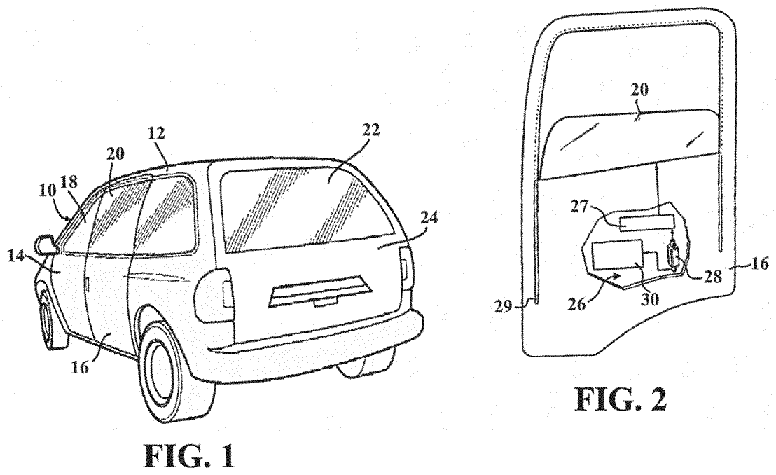

Now referring initially to FIG. 1 of the drawings, an example of a motor vehicle 10 is shown having a vehicle body 12, a hinged front door 14 and a sliding rear door 16. Front door 14 is equipped with a window 18 which is moveable between closed and open positions via a power-operated window lift system. Similarly, rear door 16 is equipped with a window 20 which is moveable between closed and open positions via a power-operated window lift system. While the present disclosure will hereinafter be specifically directed to describing the window lift system associated with rear sliding door 16, those skilled in the art will recognize and appreciate that similar arrangements to that described herein can be adapted for use with front door 14 and/or a window 22 associated with a hinged liftgate 24, as well as any other type of closure panel, and as well as other vehicle power actuators, such as for power release, power lock in vehicle door latches, as well as for cinching actuators, and the like.

As best shown in FIG. 2, an automotive power actuator unit 26 of the power-operated window lift system for the motor vehicle 10, in particular a window regulator is provided. The power actuator unit 26 is operable for driving the slider pane or window 20 of FIGS. 1 and 2 through a coupling 27, between open and closed positions with respect to a supporting frame 29, fixed to the door 16. The power operated actuator 26 includes an electric motor 28, and a controller unit 30, electrically coupled to the electric motor 28, and including (as will be discussed in the following) suitable hardware and/or software to control the operation of the electric motor 28.

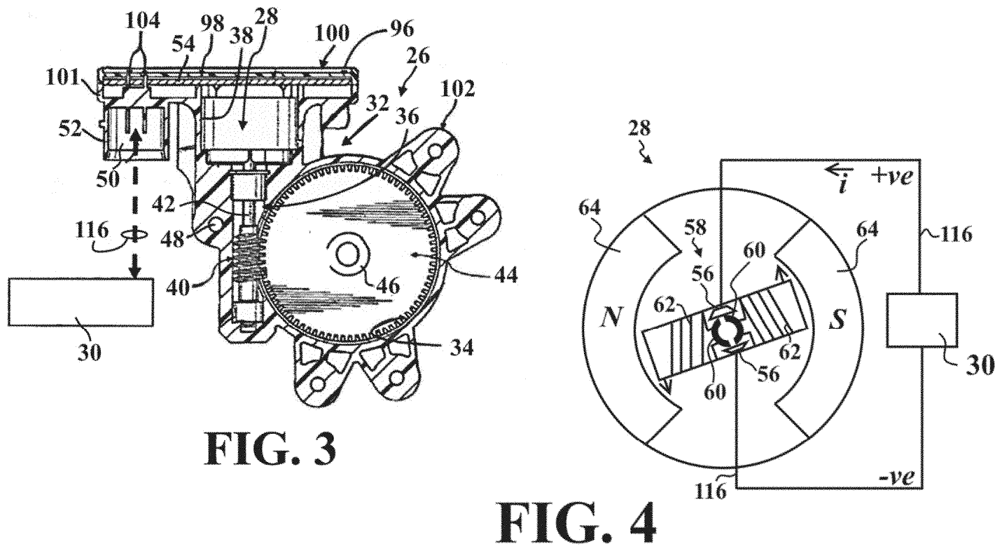

Now referring to FIG. 3, there is illustrated an example of the power actuator unit 26. In accordance with an illustrative example, powered operated actuator unit 26 may be a powered actuator unit having a brushed direct current motor (BDC). FIG. 3 also more specifically illustrates powered actuator unit 26 including a drive housing 32 for the electric motor 28. Drive housing 32 defines a gear chamber 34, a motor shaft chamber 36 communicating with gear chamber 34, and a motor mounting chamber 38 communicating with shaft chamber 36. A worm 40 fixed to motor shaft 42 is meshed with a large gear drive gear 44 that is rotatably supported in gear chamber 34. Rotation of the large gear 44 includes an output shaft 46 operably connected to a drum (not shown) to control rotation of the drum associated with a cable-pulley drive mechanism when large gear 44 rotates. The electric motor 28, is mounted in mounting chamber 38 and is operable to control the amount and direction of rotation of motor shaft 42. Housing 32 includes several apertured mounting lugs 48 for securing powered actuator unit 26 to door 16. Control signals, provided from the controller unit 30, are supplied to powered actuator unit 26. Illustratively, the controller unit 30 is shown to be remote from the motor 28 and electrically connected therewith via a wiring harness 50 having one end secured in a plug in electrical connector 52 extending from mounting chamber 38. Control signals, may alternatively be provided from a locally-located controller unit 30, for example as mounted to a printed circuit board (PCB) 54 disposed within the drive housing 32.

Now referring to FIG. 4, motor 28 is illustrated as a 2-pole permanent magnet motor, and includes a pair of motor brushes 56, such as carbon brushes, and an armature 58 having two commutator poles 60 each connected to a set of armature windings 62. The armature 58 rotates as electrical current supplied from the controller unit 30 is passed from one armature winding 62 to the next via the brushes 56 contacting the poles 60 to energize the armature windings and produce a magnetic field to attract or repel the armature towards or away from the permanent magnets 64. As the armature 58 rotates the motor brushes 56 create a short circuit between each adjacent commutator poles 60. Such a short circuit will decrease the armature resistance and cause an increase in the supplied current flow, thereby causing a ripple in the current proportional to a rotational speed of the motor 28 as generated by the induction of magnetic energy onto the motor commutator poles 60, which will be detected in a manner as will be described herein below. It is recognized other configurations of the brushed motor 28 may be provided other than a 2-pole magnet motor.

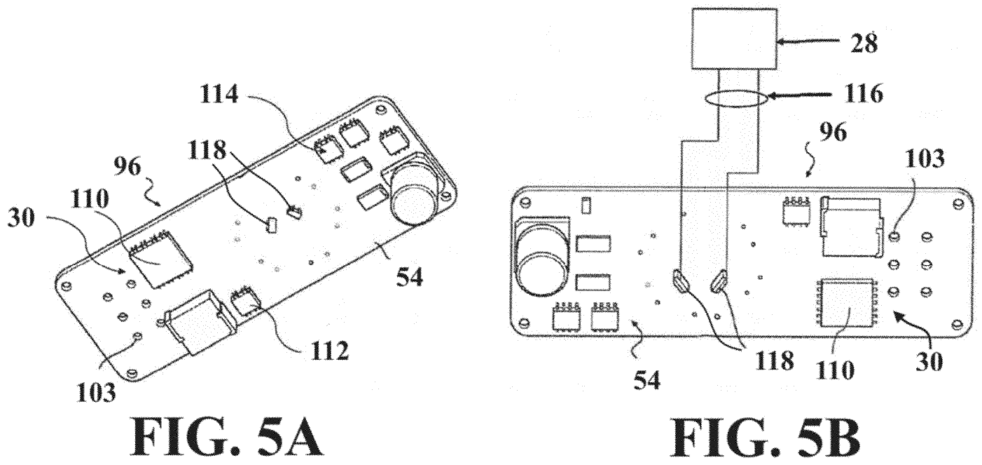

Now referring to FIGS. 5A and 5B, in addition to FIG. 3, there is illustratively shown a controller arrangement 96 embodying the controller unit 30. Controller arrangement 96 is shown to generally include the printed circuit board 54 disposed within enclosure chamber 98 upon installation of enclosure cover plate 100 onto enclosure section 101 of actuator housing 102. PCB 54 is shown to include various electrical or electronic components for controlling operation of powered actuator unit 26. Connector ports 103 are formed in PCB 54 and are configured and arranged to receive connector terminals 104 associated with the plug-in electrical connector 50 provided in connector section 52 of housing 102. The electronics mounted to the PCB 54 and electrically interconnected with one another may include hardware and software components such as a microcontroller or controller 110, such as a microprocessor, and memory modules 112, such as a memory chip, for storing instructions and algorithms (e.g., code) for execution by the controller 110 of the motor control methods and techniques as described herein. Other components such as resistors, inductors, and capacitors and other signal conditioning/supporting components for operating the controller 110 and memory modules 112 to control the motor 28 are provided. For example, instructions and code stored on the memory module 112 may also be related to various system modules, for example application programming interfaces (API) modules, drive API, digital input output API, Diagnostic API, Communication API, and communication drivers for LIN communications and CAN bus communications with a body control module (BCM) or other vehicle system. While modules or units may be described herein as being loaded into a memory 112, it is understood that the modules or units could be implemented in hardware and/or software. Also mounted to the PCB 54 may be FET hardware such as an H Bridge FET 114 (Field Effect Transistors) for providing a Pulse Width Modulated signal to the windings 62, such as the power transistor switches, and software loaded into the memory 112 related to such FETs 114, such as FET APIs.

The instructions and algorithms (e.g., code) for execution by the controller 110 (for motor monitoring/control methods and techniques) may relate to the control of a motor driver circuit 115 having H Bridge FET(s) 114 (including Field Effect Transistors, such as power transistor switches) to provide coordinated power to the motor 28, e.g., FETS 114 controlled as load switches to connect or disconnect a power source 133 of electrical energy (voltage/current) as controlled by the controller 110 or a FET driver to control the motor 28. Illustratively, the controller 110 is electrically directly or indirectly connected to the H Bridge FET 114 for control thereof (e.g., for controlling of FET switching rate). The H Bridge FET 114 is shown as illustratively connected to the motor 28 via electrical lines 116 (e.g. 2 lines, +ve and −ve) which are connected to connector pins 118 mounted to the printed circuit board 54. Sensed current signals as well as back electromotive force (EMF) voltage signals generated by the rotation of the motor 28 may also be illustratively received by the controller 110 through the same electrical lines 116. While controller unit 30 is illustrated as being embodied in the powered actuator unit 26 for a window regulator, it should be understood that controller unit 30 may be integrated into another system, such as powered door opening actuator for controlling the closing or opening of door 14, 16, 24, or within a separate door control module mounted to the door 14, 16, 24 which may be provided with an internal printed circuit board, such as PCB, microprocessor, memory, and FETs, for example.

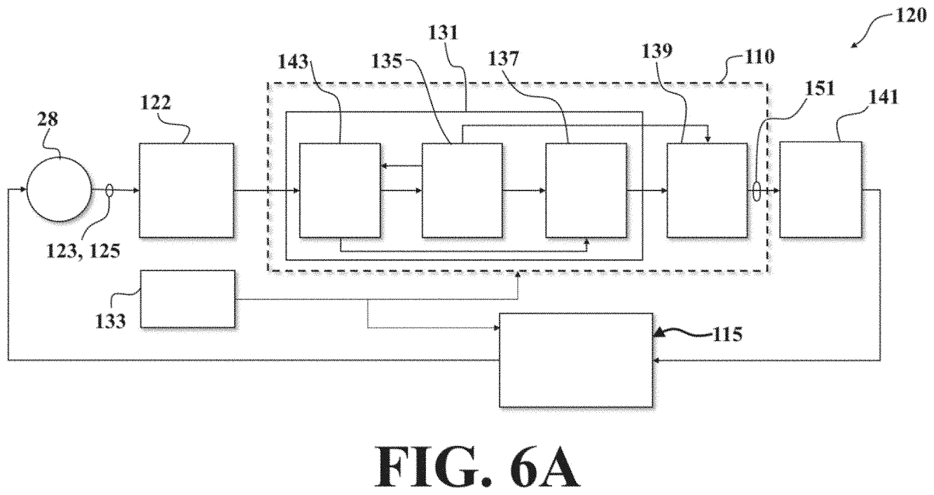

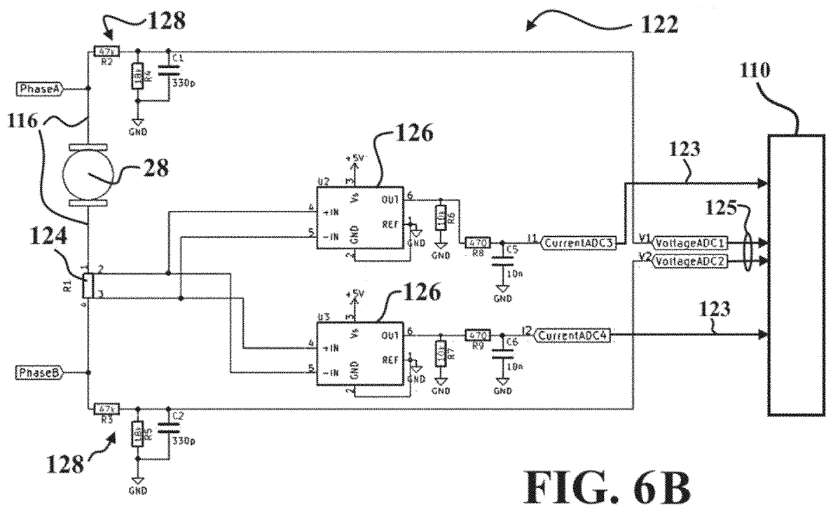

The controller unit 30 includes a control system 120 (FIG. 6A, 7) for controlling the electric motor 28 of the power actuator unit 26. The control system 120 includes a motor voltage and current sensing circuit 122 for sensing a motor current 123 and a motor voltage 125 of the electric motor 28 and outputting a corresponding motor current signal and motor voltage signal, as best shown in FIG. 6B. In more detail, the motor voltage and current sensing circuit 122 includes a four-terminal shunt resistor 124 (e.g., Bourns CST0612) in series with the electric motor 28. Two current sense amplifiers 126 (e.g., Texas Instruments INA286-Q1) are coupled to the four-terminal shunt resistor 124 to sense current in two directions. Two voltage dividers 128 are also coupled to the four-terminal shunt resistor 124 to provide voltage sensing in two directions. While the motor voltage and current sensing circuit 122 can be implemented as illustrated, it should be appreciated that the motor voltage and current sensing circuit 122 could instead be implemented using various other circuits capable of sensing the motor current and motor voltage of electric motor 28. The ripple detection controller 110 includes for example a signal acquisition unit 143 coupled to the motor voltage and current sensing circuit 122, a model estimate unit 135 coupled to the signal acquisition unit 143, a signal filtering unit 137 coupled to the signal acquisition unit 143, and to the model estimate unit 135. Signal acquisition unit 143, model estimate unit 135 and signal acquisition unit 143 form a signal preconditioning unit 131. Controller 110 further includes a peak analysis unit 139 coupled to the signal preconditioning unit 131, and for example coupled to the signal filtering unit 137, to model estimate unit 135 and the signal acquisition unit 143. Peak analysis unit 139 may be coupled to a motor control unit 141 such that peak analysis unit 139 is configured to output 151 at least one of a motor speed, and a motor position, e.g. motor rotations, based on the detected peaks in manners as describe herein. Motor control unit 141 is configured to receive the output 151 of the at least one of a motor speed, and a motor position and execute a control operation of the motor 28, for example execute a feedback control methodology such as a PID control, as one example and without limitation. Motor controller unit 141 may be coupled to a motor driver unit 115, which may take the form of application specific integrated circuits having field effect transistors (“FETs”) coupled to the motor 28 to control power supplied to the motor 28 from power source 133 for example to drive the motor 28 in different directions, and/or speeds. Motor control unit 141 may be configured with anti-pinch functionality which employs the output 151 of the at least one of a motor speed, and a motor position for providing pinch detection such that motor control unit 141 may control motor 28 to either stop or reverse direction when a pinch is detected by motor control unit 141. Output 151 may be provided to other types of systems, such as obstacle detection and warning systems, stall detection system as but examples. Units 143, 135, 131, 137, 139, 131 may be provided units as being loaded into a memory of a digital signal processor for example, as embodied as executable instructions, such as in firmware, software, source code, the like, but it is understood that the modules or units could be implemented in hardware and/or software, for example as dedicated signal processing chipsets, field programmable gate arrays, ASICs, and the like without limitation and in various combinations.

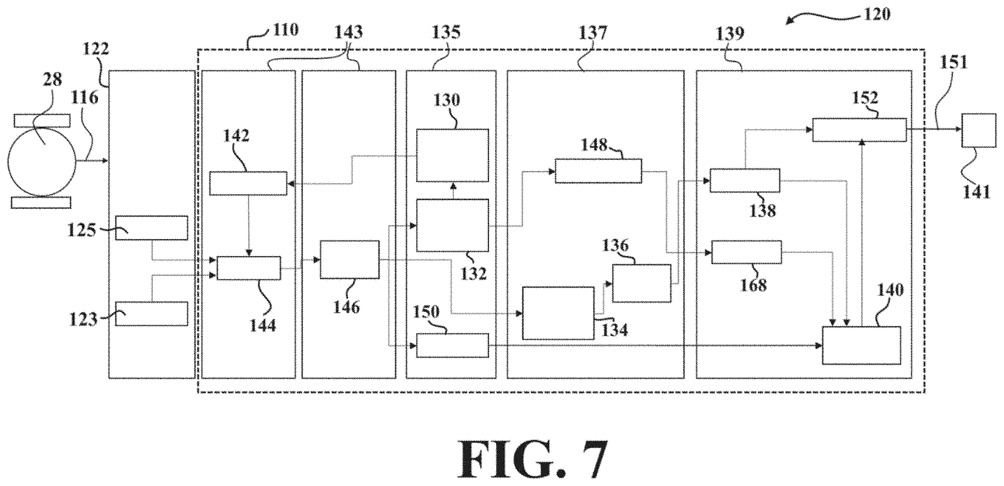

As best shown in FIG. 7, the control system 120 also encompasses the controller 110 coupled to the motor voltage and current sensing circuit 122 that includes a dynamic period estimation unit 130 and a direct current motor model unit 132 and a direct current removal digital filter unit 134 and a digital bandpass filter unit 136 and a peak detection unit 138 and a peak counting unit 140. The controller 110 may also utilize other units or modules, such as an analog to digital conversion timing unit 142 that is in communication with the dynamic period estimation unit 130 (e.g., to receive the estimated motor speed) and an analog to digital conversion signal acquisition unit 144 in communication with the analog to digital conversion timing unit 142 and with a unit conversion unit 146 that communicates with the direct current motor model unit 132. The controller 110 may also include a moving average speed filter unit 148 in communication with the direct current motor model unit 132, a direction estimator unit 150 in communication with the unit conversion unit 146 (e.g., for moving average filtering of the motor speed estimated by the direct current motor model unit 132) and a motor speed measure unit 152 configured to output at least one of a motor rotational position and a motor speed of the electric motor 28.

The controller 110 is configured to determine an estimated motor speed of the electric motor 28 based on the motor current signal and the motor voltage signal using the direct current motor model unit 132. More specifically, the direct current motor model unit 132 uses an electrical equation representing a permanent magnet direct current motor model to generate, for example to continuously estimate a shaft speed of the electric motor 28 from the acquisition of the motor voltage signal and the motor current signal. The estimated motor speed is, for example, used to tune a sample rate by controlling a trigger timing (e.g., of the analog to digital conversion timing unit 142). Moreover, using the current and the voltage signals, an estimation of the motor direction is done (e.g., using the direction estimator unit 150).

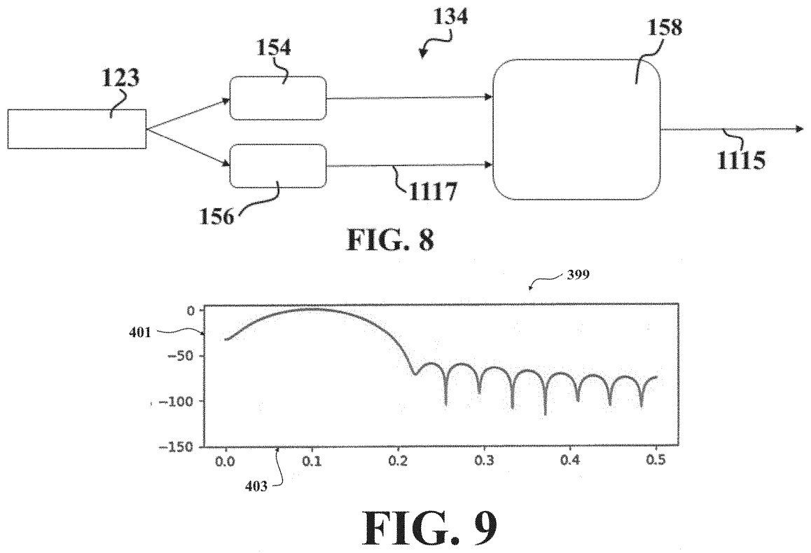

The controller 110 is also configured to remove a direct current portion of the motor current signal and extract an alternating current motor current signal using the direct current removal digital filter unit 134. As best shown in FIG. 8, the direct current removal digital filter unit 134 includes a shift register 154 configured to delay the motor current signal by a fixed phase shift factor and output a delayed motor current signal. The separation of the DC component of the current signal from the AC component by the direct current removal digital filter unit 134 is achieved by using a low pass filter using fixed coefficient. In an embodiment, the direct current removal digital filter unit 134 also includes a moving average filter 156 configured to filter the direct current portion of the motor current signal and output a direct current motor current signal 1117 (DC component of the motor current signal). The shift register 154 is necessary because the direct current moving average filter 156 introduces a phase shift between the original motor current signal and the filtered signal (DC component) 1117 and the DC component and the motor current signal have to be aligned. Thus, the original motor current signal is delayed by the fixed phase shift factor ensuring a correct synchronization between the motor current signal and filtered signal (DC component). In addition, the direct current removal digital filter unit 134 includes a subtraction unit 158 configured to subtract the direct current motor current signal 1117 from the delayed motor current signal and output the alternating current motor current signal 1115. So, the direct current (DC) part of the motor current signal is computed using digital filter (moving average), the difference between the motor current signal and the output of direct current removal digital filter unit 134 is the alternating current (AC) part of the motor current signal containing the ripple pulses or plurality of ripple peaks (caused by the commutation of the motor brush).

Referring back to FIG. 7, the controller 110 is configured to isolate the plurality of ripple peaks of the alternating current motor current signal using the digital bandpass filter unit 136 operable at a bandpass sampling frequency and having a plurality of fixed coefficients and a variable center frequency being varied by adjusting the bandpass sampling frequency in proportion to the estimated motor speed to output a bandpass filtered current signal. In general, digital filters like the digital bandpass filter unit 136 are mathematical operations that involve the sampled signal (e.g., the alternating current (AC) part of the motor current signal) and a given number of numerical coefficients. Changing the number of coefficients and their values will change the filter response. So, the filter response is dependent from the mathematical operation involved, the coefficient and also the sampling frequency. Nevertheless, changing the coefficient to change the filter response typically requires a computationally demanding operation, so the sampling frequency of the digital bandpass filter unit 136 described herein is used to change the center frequency of the digital bandpass filter unit 136. The ripple frequency is proportional to the motor shaft speed, the center frequency of the filter is changed accordingly to get only a ripple signal. Consequently, better performance, especially in transient phases of the electric motor 28, like motor start and motor brake, can be achieved.

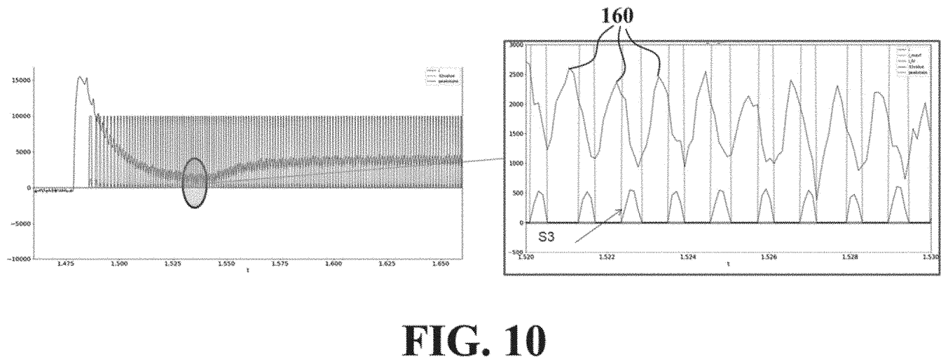

An example plot of a frequency response of the digital bandpass filter unit 136 is shown in FIG. 9. The frequency response 399 gives a representation of the attenuation of the input signal at a certain frequency after the filter computation e.g. Y-axis 401 indicates magnitude (dB) and the X-Axis 403 indicates Normalized Frequency (Xπrad/sample). The digital bandpass filter unit 136 gives less attenuation when the input signal have a frequency of the 10% of the frequency design of the filter shown. However, it should be appreciated that the digital bandpass filter unit 136 may exhibit other frequency responses. Thus, the direct current removal digital filter unit 134 and digital bandpass filter unit 136 help to extrapolate the ripple signal.

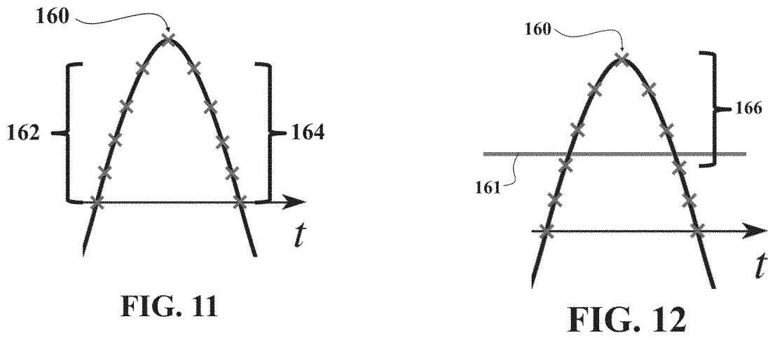

The controller 110 may be configured to determine a maxima within a predetermined period of time, such that the maxima identified by the controller 110 is a ripple peak determined by the controller 110 to be valid. For example, the controller 110 of the control system 120 then analyzes each of a plurality of possible peaks 160 of a plurality of peak detector samples, or the maxima of the sample group within the window or the predetermined period of time, of the bandpass filtered current signal within a time window of a predetermined peak detection time using the peak detection unit 138, as best shown in FIG. 10. In other words, the alternating current part of the motor current signal containing the plurality of ripple peaks is analyzed to count the peaks of the signal, both rising and falling peaks. More specifically, a window of 2k+1 time series point is built and the element at the center of the window is taken into account to be a possible peak of the signal. The controller 110 is then configured to compute a nearest point mean 161 of a predetermined quantity of the plurality of peak detector samples before and after each of the plurality of possible peaks 160 (e.g., K-nearest left quantity of points 162 and a K-nearest left quantity of points 164) using the peak detection unit 138, as best shown in FIG. 11. Next, the controller 110 is configured to compare a magnitude of each of the plurality of possible peaks 160 (e.g., distance from the nearest point mean 166) to the nearest point mean 161 using the peak detection unit 138 and determine that each of the plurality of possible peaks 160 of the bandpass filtered current signal are the plurality of peaks in response to the difference in magnitude of each of the plurality of possible peaks 160 compared to the nearest point mean 161 exceeding a predetermined peak determination threshold using the peak detection unit 138, as best shown in FIG. 12. So, a mean (e.g., nearest point mean 161) of the k-nearest point of the series of the plurality of peak detector samples from the center element or sample is computed and then a distance or magnitude from those mean 161 is compared with a threshold to establish if the point is a peak. This technique is more suitable than zero-crossing. Thus, the controller 110 is configured to detect the plurality of ripple peaks of the bandpass filtered current signal using the peak detection unit 138.

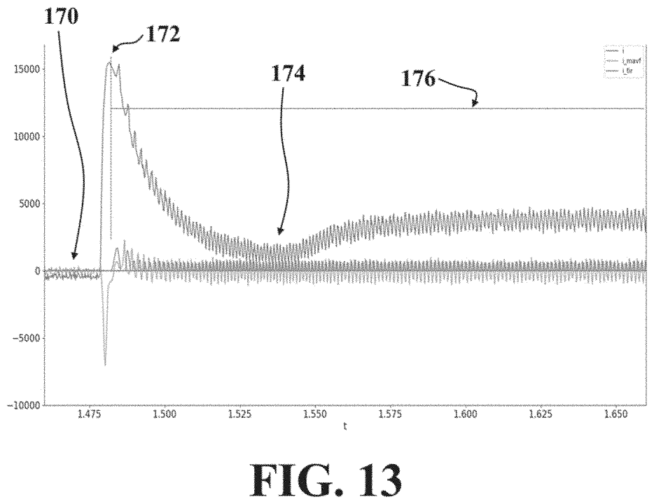

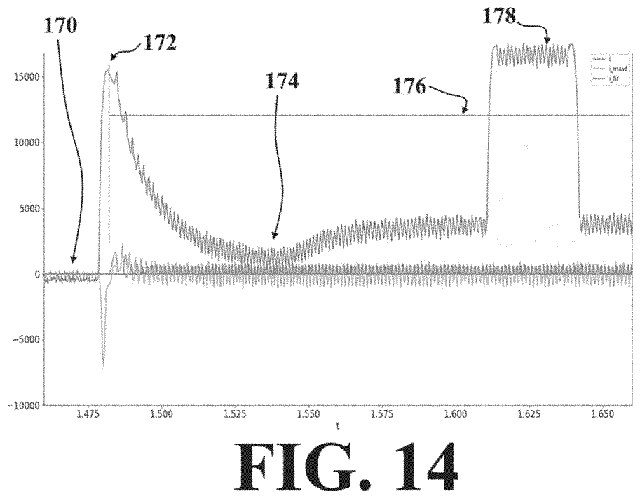

Because of the differences of motor current and motor voltage at various stages of operation of the electric motor 28, the controller 110 further includes a configuration to operate in modes or states interconnected by transitions. For example, the controller 110 may be configured with finite state machine unit 168 (FIG. 7) including or defined by the different states and transitions between states. An example plot of the motor current during operation of the electric motor 28 is shown in FIGS. 13 and 14. Specifically, an initial region 170 with no ripples or false ripples is followed by a startup spike 172, which is followed by a steady-state region 174 and the region indicated by horizontal line 176 is the period of time in which good ripple pulses can be detected. For example, each of the plurality of ripple peaks are determined by the controller 110 to be valid if an amplitude of each of the plurality of ripple peaks is below a predetermined steady state threshold, that is during a steady state operation of the motor 28, and for example the peaks of the ripple pulses being below the threshold value indicated by horizontal line 176. A stall region 178 indicating a stall condition of the electric motor 28 is shown in FIG. 14.

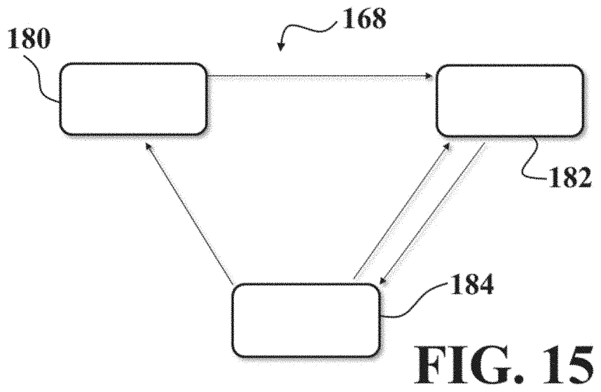

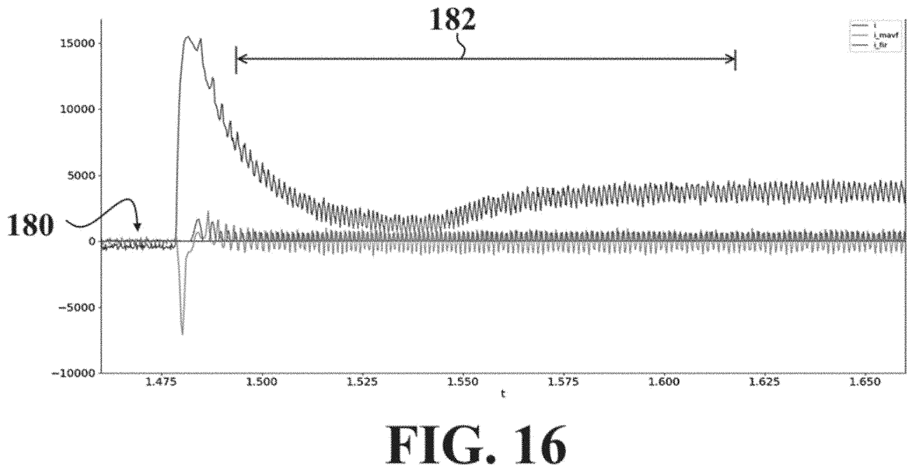

Using the finite state machine unit 168, the controller 110 is further configured to determine whether each of the plurality of peaks is valid. As best shown in FIGS. 15 and 16, the finite state machine unit 168 includes a wait state 180 and a running state 182 and a stopping state 184. So, the finite state machine unit 168 is used to check if the plurality of ripple pulses are valid or not. Specifically, the current, voltage and estimated speed signals are analyzed to establish if a detected ripple pulse can be valid based on current and voltage thresholds.

Consequently, the controller 110 is configured to analyze the motor current signal and the motor voltage signal and the estimated motor speed using the finite state machine unit 168. The controller 110 is also configured to determine one of the plurality of peaks is not valid in the wait state 180 using the finite state machine unit 168 and transition from the wait state 180 to the running state 182 in response to the motor voltage signal being above a voltage high threshold and the motor current signal being above a current high threshold and determine the one of the plurality of peaks is valid in the running state 182 using the finite state machine unit 168. Using the finite state machine unit 168, the controller 110 is additionally configured to transition from the running state 182 to the stopping state 184 in response to the motor voltage signal being below a voltage low threshold and the motor current signal being below a current low threshold and determine the one of the plurality of peaks is valid in the stopping state 184. In addition, the controller 110 is configured to transition from the stopping state 184 to the running state 182 in response to the motor voltage signal being above a voltage low threshold or the motor current signal being above a current low threshold and determine the one of the plurality of peaks is valid in the running state 182 using the finite state machine unit 168. In response to a predetermined threshold time elapsing, the controller 110 is also configured to transition from the stopping state 184 to the wait state 180 using the finite state machine unit 168 and determine the one of the plurality of peaks is not valid in the wait state 180 (a machine peak valid condition 185).

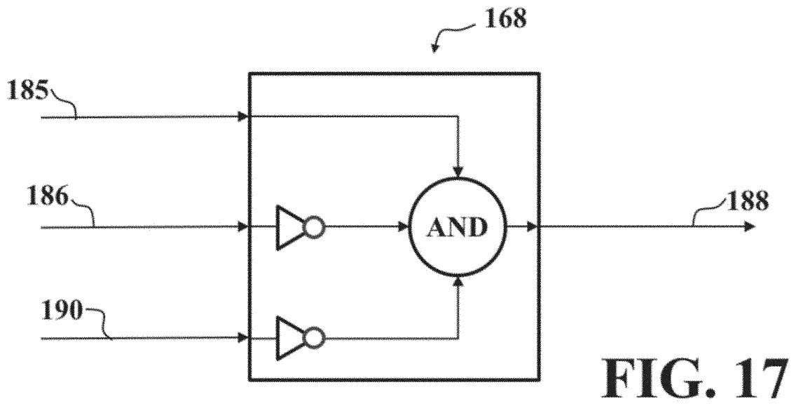

Also, as best shown in the logic diagram of FIG. 17, the controller 110 is further configured to determine a stall condition 186 is present in response to the motor current signal being above a predetermined stall current threshold for a predetermined stall period of time using the finite state machine unit 168. So, the finite state machine unit 168 checks if the motor current signal is above a certain threshold for a given time, if so, the stall condition 186 is recognized. The stall condition 186 invalidates a peak validity condition 188. The controller 110 is additionally configured to determine whether the estimated motor speed is below a predetermined under-speed motor speed using the finite state machine unit 168. If such a stall or under-speed condition 190 occurs, the controller 110 is configured to invalidate the one of the plurality of peaks being valid in response to determining the stall condition 186 using the finite state machine unit 168 and in response to determining the estimated motor speed is below the predetermined under-speed motor speed using the finite state machine unit 168 (i.e., under-speed condition 190). Thus, when the estimated speed is below a certain threshold, the one of the plurality of peaks is declared invalid by the finite state machine unit 168 (as indicated by the peak validity condition 188).

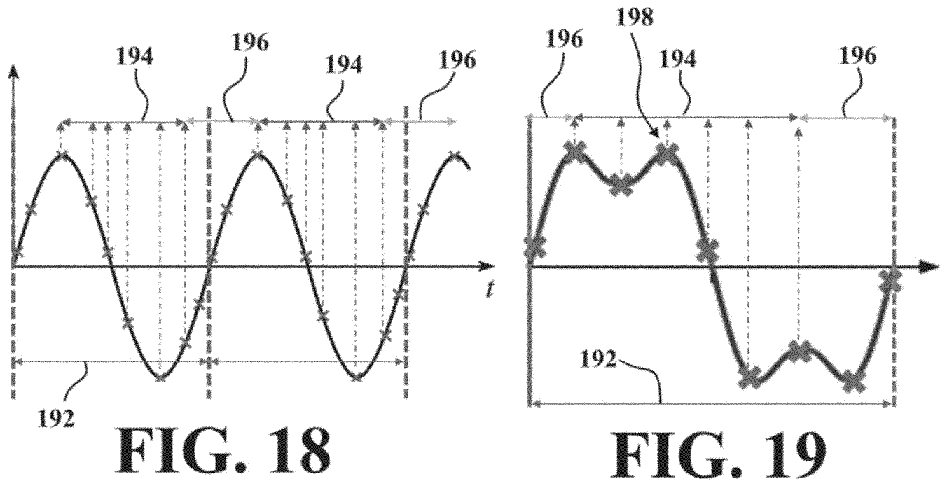

The controller 110 is configured to calculate a ripple period 192 having a plurality of ripple period samples based on the estimated motor speed of the electric motor 28. The variable sampling time implicitly feeds the controller 110 with a number of points per ripple period specified in a parameter. Consequently, as best shown in FIGS. 18 and 19, the controller 110 applies a time filter (time filter being on indicated by 194 and time filter being off indicated by 196) to ignore a predetermined quantity of ripple period samples being one half of the plurality of ripple period samples after one of the plurality of peaks is detected by the peak detection unit 138 using the peak counting unit 140. Thus, the controller 110 decreases the number of false pulses or ripples 198 detected using a temporal filter that is applied to recognize only peaks with a certain temporal separation. For example if ten points are sampled per ripple period, after a peak is recognized, the controller 110 waits for five points to start recognizing another peak. So, the controller 110 is configured to remove the time filter (time filter off indicated by 196) after the predetermined number of ripple period samples have been ignored to continue to count the plurality of peaks using the peak counting unit 140. Additionally, the controller 110 is configured to count the plurality of ripple peaks using the peak counting unit 140 and determine the motor rotational position and/or motor speed of the electric motor 28 based on a quantity of the plurality of ripple peaks counted by the peak counting unit 140.

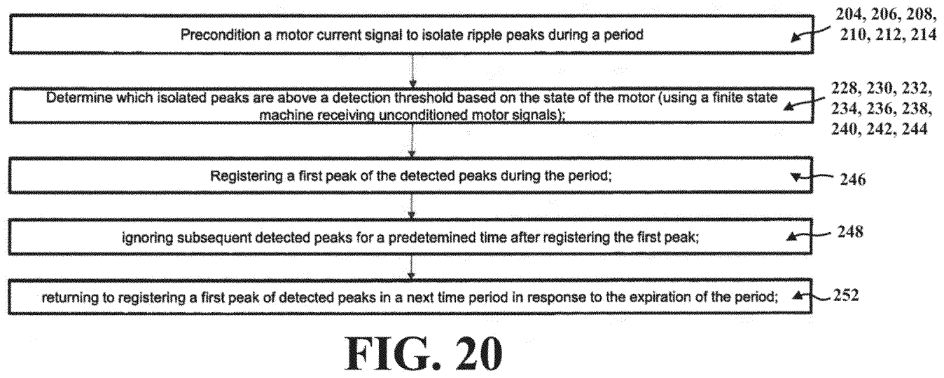

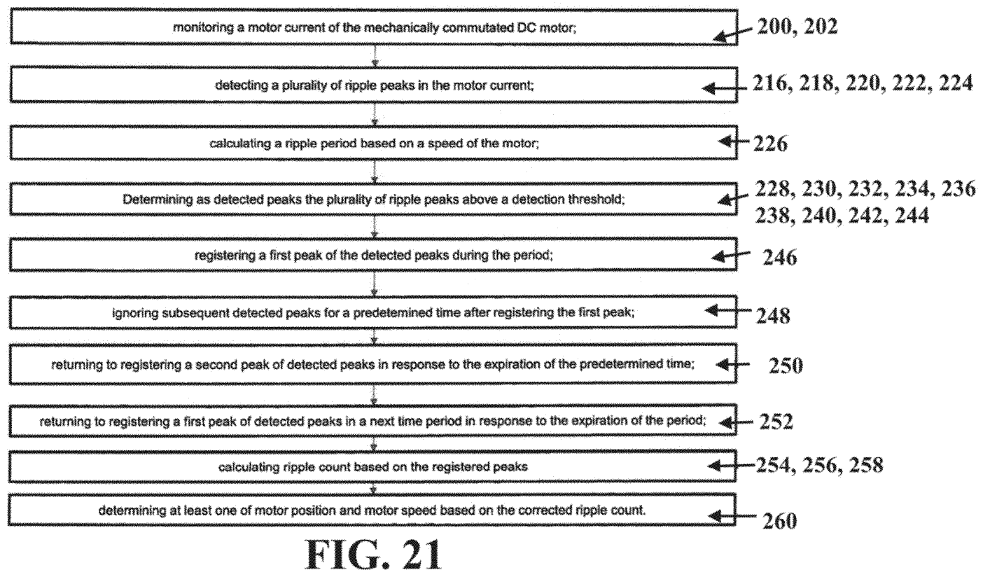

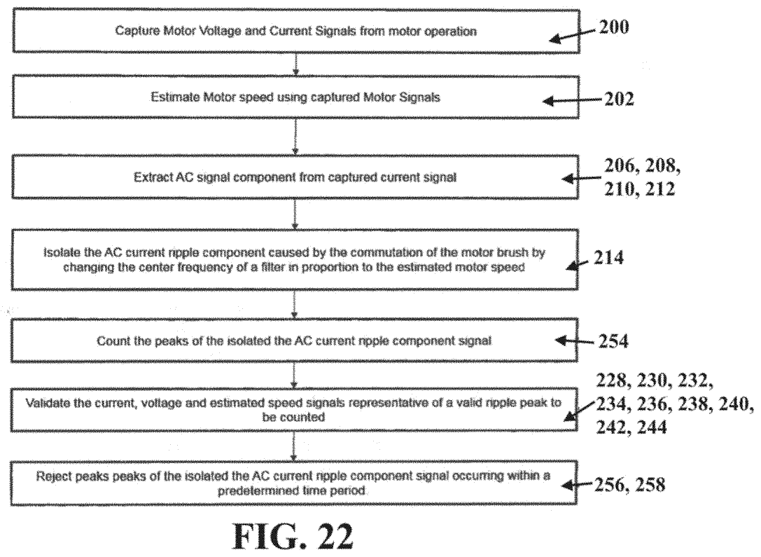

As best shown in FIGS. 20-22, a method for determining at least one of a motor rotational position and a motor speed of a mechanically commutated direct current electric motor 28 from a plurality of ripple peaks of a motor current due to commutation of the mechanically commutated direct current electric motor 28 is also provided (e.g., using a control system 120 including a controller 110). The method begins with the step of 200 monitoring a motor current of the mechanically commutated direct current motor and outputting a motor current signal and a motor voltage signal using a motor voltage and current sensing circuit 122 of the controller 110. In addition, the method includes the step of 202 determining an estimated motor speed of the electric motor 28 based on the motor current signal and the motor voltage signal using a direct current motor model unit 132 of the controller 110.

The method includes the step of 204 preconditioning the motor current signal to isolate the plurality of ripple peaks during an established period of time. As discussed above, the controller 110 includes a direct current removal digital filter unit 134, so the step of 204 preconditioning the motor current signal to isolate the plurality of ripple peaks during the established period of time includes the step of 206 removing a direct current portion of the motor current signal and extracting an alternating current motor current signal using the direct current removal digital filter unit 134. More specifically, the step of 206 removing the direct current portion of the motor current signal and extracting the alternating current motor current signal using the direct current removal digital filter unit 134 includes the step of 208 delaying the motor current signal by a fixed phase shift factor and outputting a delayed motor current signal using a shift register 154 of the direct current removal digital filter unit 134. Next, the method can continue by 210 filtering the direct current portion of the motor current signal and outputting a direct current motor current signal using a moving average filter 156 of the direct current removal digital filter unit 134. The method then includes the step of 212 subtracting the direct current motor current signal from the delayed motor current signal and outputting an alternating current motor current signal using a subtraction unit 158 of the direct current removal digital filter unit 134.

As discussed above, the controller 110 includes a digital bandpass filter unit 136. Thus, the step of 204 preconditioning the motor current signal to isolate the plurality of ripple peaks during the established period of time also includes the step of 214 isolating the plurality of ripple peaks of the alternating current motor current signal using the digital bandpass filter unit 136 operable at a bandpass sampling frequency and having a plurality of fixed coefficients and a variable center frequency being varied by adjusting the bandpass sampling frequency in proportion to the motor speed, and for example the estimated motor speed, to output a bandpass filtered current signal.

Next, the method includes 216 detecting the plurality of ripple peaks in the motor current signal using a peak detection unit 138 of the controller 110. The step of 216 detecting the plurality of ripple peaks in the motor current signal using the peak detection unit 138 of the controller 110 further includes the step of 218 analyzing each of a plurality of possible peaks of a plurality of peak detector samples of the bandpass filtered current signal within a time window of a predetermined peak detection time using the peak detection unit 138. The method continues by 220 computing a nearest point mean of a predetermined quantity of the plurality of peak detector samples before and after each of the plurality of possible peaks using the peak detection unit 138. The next steps of the method are 222 comparing a magnitude of each of the plurality of possible peaks to the nearest point mean using the peak detection unit 138 and 224 determining that each of the plurality of possible peaks of the bandpass filtered current signal are the plurality of peaks in response to the difference in magnitude of each of the plurality of possible peaks compared to the nearest point mean exceeding a predetermined peak determination threshold using the peak detection unit 138. The method can also include the step of 226 calculating a ripple period based on an estimated speed of the mechanically commutated direct current electric motor 28.

The method also includes the step of 228 determining which of the plurality of ripple peaks are above a detection threshold based on the state of the mechanically commutated direct current electric motor 28 (e.g., using a finite state machine unit 168 of the controller 110 receiving the motor current signal being unconditioned and a motor voltage signal being unconditioned). In more detail, the step of 228 determining which of the plurality of ripple peaks are above the detection threshold based on the state of the mechanically commutated direct current electric motor 28 can include the steps of 230 analyzing the motor current signal and the motor voltage signal and the estimated motor speed using the finite state machine unit 168. The method can proceed by 232 determining one of the plurality of peaks is not valid in the wait state 180 using the finite state machine unit 168. The next step of the method is 234 transitioning from the wait state 180 to the running state 182 in response to the motor voltage signal being above a voltage high threshold and the motor current signal being above a current high threshold and determine the one of the plurality of peaks is valid in the running state 182 using the finite state machine unit 168. The method can continue with the step of 236 transitioning from the running state 182 to the stopping state 184 in response to the motor voltage signal being below a voltage low threshold and the motor current signal being below a current low threshold and determine the one of the plurality of peaks is valid in the stopping state 184 using the finite state machine unit 168. The, the next step of the method is 238 transitioning from the stopping state 184 to the running state 182 in response to the motor voltage signal being above a voltage low threshold or the motor current signal being above a current low threshold and determine the one of the plurality of peaks is valid in the running state 182 using the finite state machine unit 168. The method can also include the step of 240 transitioning from the stopping state 184 to the wait state 180 in response to a predetermined threshold time has elapsed and determine the one of the plurality of peaks is not valid in the wait state 180 using the finite state machine unit 168. The method can also include the steps of 242 determining a stall condition (e.g. see FIG. 14) is present in response to the motor current signal being above a predetermined stall current threshold for a predetermined stall period of time using the finite state machine and invalidating the one of the plurality of peaks being valid in response to determining the stall condition using the finite state machine unit 168. Next, the method can continue by 244 determining whether the estimated motor speed is below a predetermined under-speed motor speed using the finite state machine unit 168 and invalidating the one of the plurality of peaks being valid in response to determining the estimated motor speed is below the predetermined under-speed motor speed using the finite state machine unit 168.

The method proceeds by 246 registering a first peak of the plurality of ripple peaks during the ripple period in response to one of the plurality of ripple peaks being above the detection threshold. The method also includes the step of 248 ignoring, or not counting, subsequent ones of the plurality of ripple peaks for a predetermined period of time after registering the first peak. The method then includes the step of 250 registering one of a plurality successive peaks of the plurality of ripple peaks during another predetermined period of time in response to another of the plurality of ripple peaks being above the detection threshold after the expiration of the predetermined period of time. The method continues by 252 returning to the step of registering the first peak of the plurality of ripple peaks for another ripple period in response to the expiration of the ripple period.

The method continues with the step of 254 counting a ripple count of the first peak and the plurality successive peaks being registered. The ripple period has a plurality of ripple period samples and the step of calculating the ripple period based on the estimated speed of the mechanically commutated direct current electric motor 28 can further include the step of 256 applying a time filter to ignore a predetermined quantity of ripple period samples, for example, a predetermined quantity being at least one half of the plurality of ripple period samples, after one of the plurality of peaks is detected by the peak detection unit 138 using the peak counting unit 140 and wherein the method further includes the step of 258 removing the time filter after the predetermined number of ripple period samples have been ignored to continue to count the plurality of peaks using the peak counting unit 140. The method proceeds by 260 determining at least one of the motor rotational position and the motor speed of the mechanically commutated direct current electric motor 28 based on the ripple count.

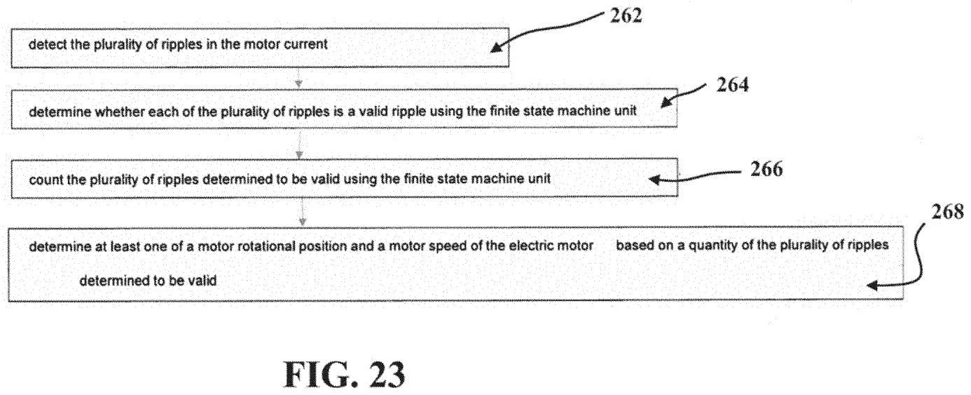

Now referring to FIG. 23, there is provided a method of validating a motor current signal for a control system 120 controlling a mechanically commutated direct current electric motor 28 of a power actuator unit of a vehicle. Again, the control system 120 includes a motor current sensing circuit 122 for sensing a motor current comprising a plurality of ripples due to commutation of the mechanically commutated direct current electric motor 28 and outputting a motor current signal. The method includes the steps of 262 configuring a controller 110 in communication with the motor current sensing circuit 122 and including a finite state machine unit 168 to detect the plurality of ripples in the motor current. Next, 264 determining whether each of the plurality of ripples is a valid ripple using the finite state machine unit 168. The next step of the method is 266 counting the plurality of ripples determined to be valid using the finite state machine unit 168. The method also includes the step of 268 determining at least one of a motor rotational position and a motor speed of the electric motor 28 based on a quantity of the plurality of ripples determined to be valid.

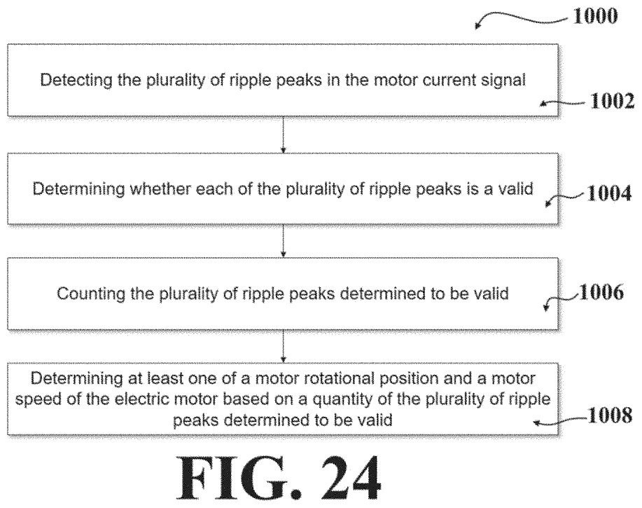

Now referring to FIG. 24, in addition to FIGS. 1 to 23, there is illustrated a method 1000 for determining at least one of a motor rotational position and a motor speed of a mechanically commutated direct current electric motor from a plurality of ripple peaks of a motor current signal due to commutation of the mechanically commutated direct current electric motor, the method 1000 including the steps of detecting the plurality of ripple peaks in the motor current signal 1002, determining whether each of the plurality of ripple peaks is a valid 1004, counting the plurality of ripple peaks determined to be valid 1006, and determining at least one of a motor rotational position and a motor speed of the electric motor based on a quantity of the plurality of ripple peaks determined to be valid 1008.

The method 1000 may further includes the steps of sampling the motor current at a sampling frequency, using a motor model to estimate the motor speed using the motor current, and varying the sampling frequency in proportional to the motor speed.

The method 1000 may further include the step of applying a filter to the motor current signal, the filter having a filter response modified in response to varying the sampling frequency. The filter may be a digital bandpass filter, and further comprising the step of using a digital moving average filter upstream the digital bandpass filter to extract a direct current component of the motor current signal before the step of applying the filter.

The method 1000 may further include the steps of calculating a mean value of each of the plurality of ripple peaks over a period, and determining if at least one peak ripple peak is above by a predetermined amount of the mean value, and validating the at least one peak ripple peak in response to determining if at least one peak is above by the predetermined amount of the mean value over a predetermined period of time.

The method 1000 may further include the steps of registering a first ripple peak of the plurality of ripple peaks during a ripple period in response to determining one of the plurality of ripple peaks, ignoring subsequent ones of the plurality of ripple peaks for a predetermined period of time after registering the first peak, registering one of a plurality successive peaks of the plurality of ripple peaks during another predetermined period of time in response to determining another of the plurality of ripple peaks after an expiration of the predetermined period of time, counting a ripple count of the first peak and the plurality successive peaks being registered, and determining at least one of the motor rotational position and the motor speed of the mechanically commutated direct current electric motor based on the ripple count. The the step of determining whether each of the plurality of ripple peaks is a valid includes the steps of analyzing the motor current signal and a motor voltage signal and the estimated motor speed, determining one of the plurality of peaks is not valid in a wait state, transitioning from the wait state to a running state in response to the motor voltage signal being above a voltage high threshold and the motor current signal being above a current high threshold and determine the one of the plurality of peaks is valid in the running state, transitioning from the running state to a stopping state in response to the motor voltage signal being below a voltage low threshold and the motor current signal being below a current low threshold and determine the one of the plurality of peaks is valid in the stopping state, transitioning from the stopping state to the running state in response to the motor voltage signal being above a voltage low threshold or the motor current signal being above a current low threshold and determine the one of the plurality of peaks is valid in the running state, and transitioning from the stopping state to the wait state in response to a predetermined threshold time has elapsed and determine the one of the plurality of peaks is not valid in the wait state.

The method 1000 may further include using a finite state machine unit having the wait state, the running state, and the stopping state.

The method 1000 may further include at least one step of determining a stall condition is present in response to the motor current signal being above a predetermined stall current threshold for a predetermined stall period of time, and invalidating the one of the plurality of peaks being valid in response to determining the stall condition, and determining whether the estimated motor speed is below a predetermined under-speed motor speed, and invalidating the one of the plurality of peaks being valid in response to determining the estimated motor speed is below the predetermined under-speed motor speed.

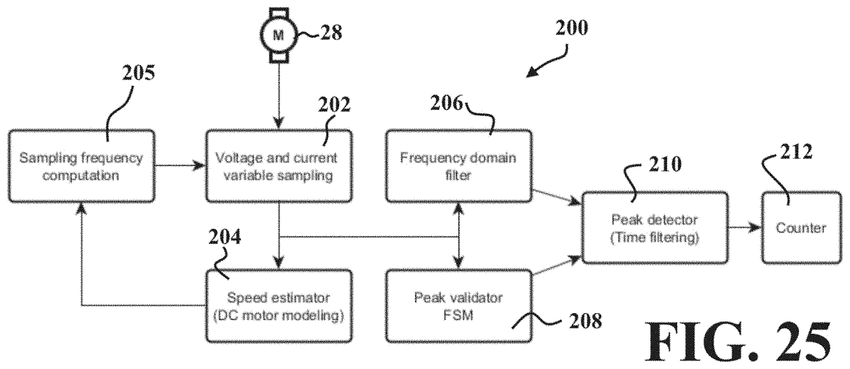

Now referring to FIG. 25, in addition to FIGS. 1 to 24, there is provided a detection system 200 embodying the teachings herein, including a voltage and current variable sampling unit 202, for example signal acquisition unit 143, for sampling a motor current having a plurality of ripple peaks as a function of a motor speed, for example an estimated motor speed, a speed estimator unit 204 having DC motor modeling, for example model estimate unit 135, coupled to the voltage and current variable sampling unit 202 for generating an estimated motor speed based on a model of the motor 28, a sampling frequency computation unit 205, for example dynamic period estimation unit 130, for determining a sampling rate of the motor signal as a function of the estimated motor speed, such as controlling the timing of an analog to digital converter (ADC), a frequency domain filter 206, such as direct current removal digital filter unit 134 and/or digital bandpass filter unit 136 for isolating the ripple peaks in the motor current, for example isolating the ripple peaks in the motor current as a function of the estimated motor speed, and a peak validator unit 208, such as finite state machine unit 168, for validating the ripple peaks in the motor current before counting the ripple peaks in the motor current and/or for invalidating a validated ripple peak before counting the ripple peaks in the motor current, a peak detector unit 210, such as peak detection unit 138 for time filtering the filtered the motor current for detecting a ripple peak, and a counter unit 212, such as peak counting unit 140 for counting the validated ripple peaks outputted from the peak detector unit 210.

Clearly, changes may be made to what is described and illustrated herein without, however, departing from the scope defined in the accompanying claims. The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” “top”, “bottom”, and the like, may be used herein for ease of description to describe one element's or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptions used herein interpreted accordingly.

What is claimed is:

1. A system for determining at least one of a rotational position and a speed of a mechanically commutated direct current electric motor of a power actuator unit of a vehicle, comprising:
a motor current sensing circuit for sensing a motor current comprising a plurality of ripples due to commutation of the mechanically commutated direct current electric motor and outputting a motor current signal; and
a controller in communication with the motor current sensing circuit, the controller configured to:
receive the motor current signal comprising a plurality of ripple peaks,
determine whether the plurality of ripple peaks are valid,
count the plurality of ripple peaks determined to be valid, and
determine at least one of the rotational position and the speed of the electric motor based on a quantity of the plurality of ripple peaks determined to be valid.

2. The system as set forth in claim 1, wherein each of the plurality of ripple peaks are determined by the controller to be valid if an amplitude of each of the plurality of ripple peaks is below a predetermined steady state threshold.

3. The system as set forth in claim 2, wherein the controller is configured to analyze the motor current signal comprising a plurality of ripple peaks for a predetermined period of time, and determine a maxima within the predetermined period of time, wherein the maxima is a ripple peak determined by the controller to be valid.

4. The system as set forth in claim 3, wherein the controller is further configured to calculate a ripple period based on the speed of the electric motor, wherein a first ripple peak determined by the controller to be valid within the ripple period is counted and subsequent ripple peaks within the ripple period are not counted.

5. The system as set forth in claim 1, wherein said motor current sensing circuit is configured to sense a motor voltage of the electric motor and output a motor voltage signal, and said controller is further configured to:
analyze the motor current signal and the motor voltage signal,
determine one of the plurality of ripple peaks is not valid in a wait state,
transition from said wait state to a running state in response to the motor voltage signal being above a voltage high threshold and the motor current signal being above a current high threshold and determine the one of the plurality of ripple peaks is valid in said running state,
transition from said running state to a stopping state in response to the motor voltage signal being below a voltage low threshold and the motor current signal being below a current low threshold and determine the one of the plurality of ripple peaks is valid in said stopping state,
transition from said stopping state to said running state in response to the motor voltage signal being above a voltage low threshold or the motor current signal being above a current low threshold and determine the one of the plurality of ripple peaks is valid in said running state, and
transition from said stopping state to said wait state in response to a predetermined threshold time has elapsed and determine the one of the plurality of peaks is not valid in said wait state.

6. The system as set forth in claim 5, wherein the controller comprises a finite state machine unit including the wait state and the running state and the stopping state.

7. The system as set forth in claim 6, wherein said controller is further configured to determine at least one of a stall condition is present in response to the motor current signal being above a predetermined stall current threshold for a predetermined stall period of time and an estimated motor speed of the electric motor based on the motor current signal and the motor voltage signal, and is further configured invalidate the one of the plurality of peaks being valid in response to determining at least one of the stall condition being present and the estimated motor speed is below a predetermined under-speed motor speed.

8. The system as set forth in claim 1, wherein the controller includes a digital bandpass filter unit for isolating the plurality of ripple peaks, the digital bandpass filter unit operable at a bandpass sampling frequency and having a plurality of fixed coefficients and a variable center frequency being varied by adjusting the bandpass sampling frequency in proportion to the motor speed to output a bandpass filtered current signal.

9. The system as set forth in claim 8, wherein the controller includes a motor model unit to generate an estimated motor speed using the motor current signal, wherein the variable center frequency being varied by adjusting the bandpass sampling frequency is in relation to the estimated motor speed.

10. The system as set forth in claim 9, wherein the controller further includes a direct current removal digital filter unit for removing a direct current portion of the motor current signal and extracting an alternating current motor current signal using the direct current removal digital filter unit, wherein the digital bandpass filter unit is configured to receive the alternating current motor current signal.

11. The system as set forth in claim 10, wherein the controller includes a peak detection unit for:
analyzing each of a plurality of possible peaks of a plurality of peak detector samples of the bandpass filtered current signal within a time window of a predetermined peak detection;
computing a nearest point mean of a predetermined quantity of the plurality of peak detector samples before and after each of the plurality of possible peaks;
comparing a magnitude of each of the plurality of possible peaks to the nearest point mean using the peak detection unit; and
determining that each of the plurality of possible peaks of the bandpass filtered current signal are the plurality of peaks in response to a difference in magnitude of each of the plurality of possible peaks compared to the nearest point mean exceeding a predetermined peak determination threshold using the peak detection unit.

12. The system as set forth in claim 11, wherein said controller is further configured to:
calculate a ripple period having a plurality of ripple period samples based on the estimated motor speed of the electric motor,
apply a time filter to ignore a predetermined quantity of ripple period samples after one of the plurality of peaks is detected by said peak detection unit using said peak counting unit, and
remove the time filter after the predetermined quantity of ripple period samples have been ignored to continue to count the plurality of peaks using said peak counting unit.

13. A method for determining at least one of a motor rotational position and a motor speed of a mechanically commutated direct current electric motor from a plurality of ripple peaks of a motor current signal due to commutation of the mechanically commutated direct current electric motor, the method comprising the steps of:
detecting the plurality of ripple peaks in the motor current signal;
determining whether each of the plurality of ripple peaks is a valid;
counting the plurality of ripple peaks determined to be valid; and
determining at least one of a motor rotational position and a motor speed of the electric motor based on a quantity of the plurality of ripple peaks determined to be valid.

14. The method as set forth in claim 13, further comprising the steps of:
sampling the motor current at a sampling frequency;
using a motor model to estimate the motor speed using the motor current; and
varying the sampling frequency in proportional to the motor speed.

15. The method as set forth in claim 14, further comprising the step of applying a filter to the motor current signal, the filter having a filter response modified in response to varying the sampling frequency.

16. The method as set forth in claim 15, wherein the filter is a digital bandpass filter, and further comprising the step of using a digital moving average filter upstream the digital bandpass filter to extract a direct current component of the motor current signal before the step of applying the filter.

17. The method as set forth in claim 16, further comprising the steps of;
calculating a mean value of each of the plurality of ripple peaks over a period; and
determining if at least one peak ripple peak is above by a predetermined amount of the mean value; and
validating the at least one peak ripple peak in response to determining if at least one peak is above by the predetermined amount of the mean value over a predetermined period of time.

18. The method as set forth in claim 17, further comprising the steps of:
registering a first ripple peak of the plurality of ripple peaks during a ripple period in response to determining one of the plurality of ripple peaks;
ignoring subsequent ones of the plurality of ripple peaks for a predetermined period of time after registering the first peak;
registering one of a plurality successive peaks of the plurality of ripple peaks during another predetermined period of time in response to determining another of the plurality of ripple peaks after an expiration of the predetermined period of time;
counting a ripple count of the first peak and the plurality successive peaks being registered; and
determining at least one of the motor rotational position and the motor speed of the mechanically commutated direct current electric motor based on the ripple count.

19. The method as set forth in claim 13, wherein the step of determining whether each of the plurality of ripple peaks is a valid includes the steps of:
analyzing the motor current signal and a motor voltage signal and the estimated motor speed;
determining one of the plurality of peaks is not valid in a wait state;
transitioning from the wait state to a running state in response to the motor voltage signal being above a voltage high threshold and the motor current signal being above a current high threshold and determine the one of the plurality of peaks is valid in the running state;
transitioning from the running state to a stopping state in response to the motor voltage signal being below a voltage low threshold and the motor current signal being below a current low threshold and determine the one of the plurality of peaks is valid in the stopping state;
transitioning from the stopping state to the running state in response to the motor voltage signal being above a voltage low threshold or the motor current signal being above a current low threshold and determine the one of the plurality of peaks is valid in the running state; and
transitioning from the stopping state to the wait state in response to a predetermined threshold time has elapsed and determine the one of the plurality of peaks is not valid in the wait state.

20. A detection system for determining at least one of a motor rotational position and a motor speed of a mechanically commutated direct current electric motor from a plurality of ripple peaks of a motor current signal due to commutation of the mechanically commutated direct current electric motor, the detection system comprising a voltage and current variable sampling unit for sampling the motor current signal having a plurality of ripple peaks as a function of a motor speed, a speed estimator unit for generating an estimated motor speed based on a model of the motor, a sampling frequency computation unit for determining a sampling rate of the motor current signal as a function of the estimated motor speed, a frequency domain filter for isolating the ripple peaks in the motor current signal, a peak validator unit for at least one of validating the ripple peaks in the motor current signal before counting the ripple peaks in the motor current signal and for invalidating a validated ripple peak before counting the ripple peaks in the motor current signal, a peak detector unit for time filtering the filtered motor signal current for detecting the ripple peak, and a counter unit for counting the validated ripple peaks outputted from the peak detector unit.
